(19) United States
(12) Patent Application Publication
(10) Pub. No.: US 2007/0267216 A1
(43) Pub. Date: Nov. 22, 2007

(54) Base of a circuit board with a heat dissipating capability

(76) Inventor: Li-Wei Kuo, Bade City (TW)

Correspondence Address: Frenkel & Associates, P.C.;Suite 330, 3975 University Drive, Fairfax, VA, 22030, US

(21) Appl. No.: 11/435,086

(22) Filed: May 16, 2006

(51) Int. Cl. H05K 1/00

(52) U.S. Cl. 174/252

(57) ABSTRACT

A base for a circuit board has a body made of metal material with a high heat conduction and an isolated heat conduction layer mounted on the body for preventing short circuit from occurring. Hence, the heat-generated by an electrical component can be effectively dissipated via the isolated heat conduction layer.

### BACKGROUND OF THE INVENTION

1. Field of the Invention

The present invention relates to a base, and more particularly to a base of a circuit board and having a heat dissipating capability.

2. Description of the Related Art

To connect electrical components, wires are respectively welded manually among terminals of the electrical components to generate a current loop. However, the electrical components are always arranged in a high density to perform much more function, but is time consuming in assembling. Furthermore, it is easy to cause short cut when the electrical components are connected with wires manually.

Hence, a conventional circuit board is introduced into the market to overcome the foresaid shortcoming and has circuits printed on the circuit board and terminals of the electrical components are directly connected to the circuits. Consequently, to assemble electrical components on to a circuit board is easy and highly effective.

With reference to FIG. 2, a conventional circuit board in accordance with the prior art has a base (50) and circuits (60) made of copper foil provided on a surface of the base (50). The base (50) is made of FR4, FR5, epoxy resin or silicon. However, although the base (60) is isolated from the circuit (60) and can endure a high temperature, electrical components on the base (50) can not dissipate heat via the base (50) such that the circuit board is easily damaged and has a low efficiency after a term of operation.

Therefore, the invention provides a base of a circuit board to mitigate or obviate the aforementioned problems.

### SUMMARY OF THE INVENTION

The main objective of the present invention is to provide a base of a circuit board and having a heat dissipating capability.

Other objectives, advantages and novel features of the invention will become more apparent from the following detailed description when taken in conjunction with the accompanying drawings.

### BRIEF DESCRIPTION OF THE DRAWINGS

FIG. 1 is a side view in partial section of a circuit board with a base in accordance with the present invention; and

FIG. 2 is a s side view in partial section of a conventional circuit card.

### DETAILED DESCRIPTION OF THE PREFERRED EMBODIMENT

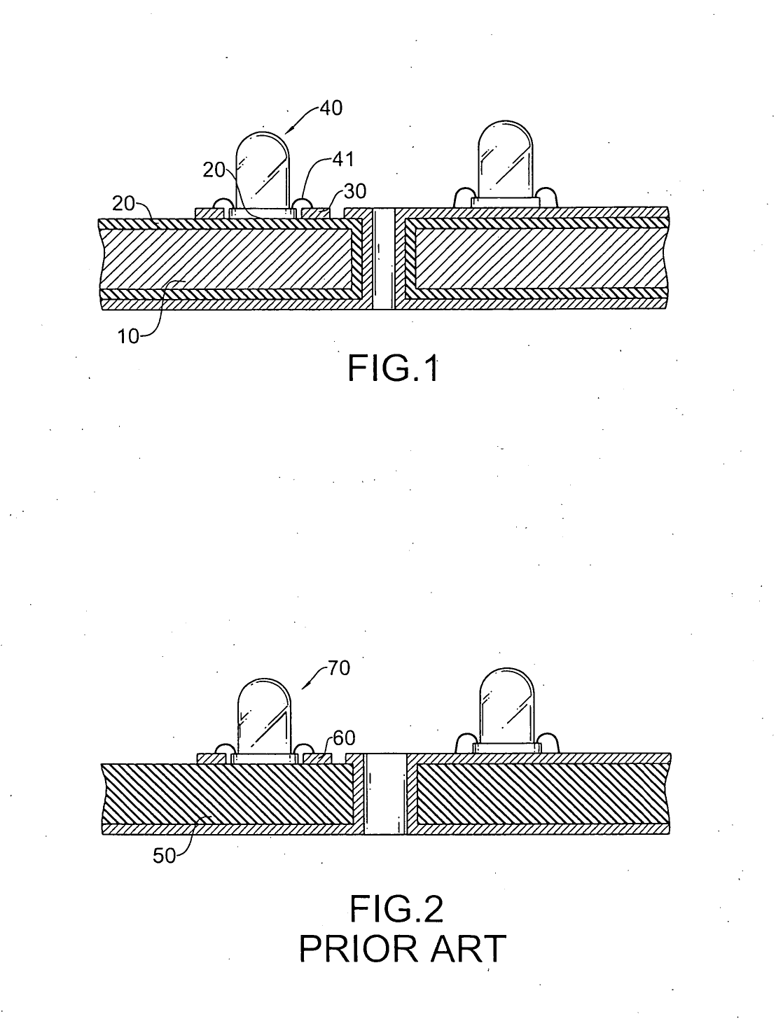

With reference to FIG. 1, a base for a circuit board in accordance with the present invention comprises a body (10) and an isolated heat conducting layer (20). The body (10) is made of metallic material such as aluminum or copper with a high heat conduction. The isolated heat conducting layer (20) is made of an isolated heat conducting glue and is mounted on the base (10) and solidified by roasting.

A copper foil is mounted on the isolated heat conducting layer (20) to form circuits (30) with etching or other methods. Terminals (41) of an electrical component, such as an LED (40) are connected to the circuits (30) so that the LED (40) emits light when power is switched on. Furthermore, the LED (40) is isolated from the body (10) due to the isolated heat conducting layer (20) thereby preventing short circuit from occurring. Additionally, a lower end of the LED (40) contacts with the isolated heat conducting layer (20) so that the heat generated from the LED (40) conducts through the isolated heat conducting layer (20) and is dissipated. Accordingly, the LED (40) can sustain a low heat to keep an excellent operation efficiency in stable.

It is to be understood, however, that even though numerous characteristics and advantages of the present invention have been set forth in the foregoing description, together with details of the structure and function of the invention, the disclosure is illustrative only. Changes may be made in details, especially in matters of shape, size, and arrangement of parts within the principles of the invention to the full extent indicated by the broad general meaning of the terms in which the appended claims are expressed.

1. A base for a circuit board comprising:
a body made of metallic material;
an isolated heat conducting layer mounted on a topper end of the body for preventing short circuit from occurring and providing a heat dissipating capability; and
a copper foil being directly mounted on the isolated heat conducting layer to form circuits on the isolated heat conducting layer.

2. The base as claimed in claim 1, wherein the body is made of copper.

3. The base as claimed in claim 1, wherein the body is made of aluminum.

4. (canceled)

5. The base as claimed in claim 1, wherein at least one electrical component is connected to the circuits on the isolated heat conducting layer.

6. (canceled)
